(19) United States
(12) Patent Application Publication
(10) Pub. No.: US 2015/0207035 A1
(43) Pub. Date: Jul. 23, 2015

(54) Light-Emitting Element Having a Tunneling Structure

(71) Applicant: EPISTAR CORPORATION, Hsinchu (TW)

(72) Inventors: Miao-Chan TSAI, Hsinchu (TW); Benajmin LEUNG, Hsinchu (TW); Ta-Cheng HSU, Hsinchu (TW)

(73) Assignee: EPISTAR CORPORATION, Hsinchu (TW)

(21) Appl. No.: 14/158,575

(22) Filed: Jan. 17, 2014

(51) Int. Cl. H01L 33/32; H01L 33/00

(52) U.S. Cl. CPC H01L 33/32; H01L 33/0025

(57) ABSTRACT

A light-emitting element includes a first light-emitting stacked structure including a first active layer; and a tunneling structure on the light-emitting stacked structure including a first doped semiconductor layer; a first undoped semiconductor layer on the first doped semiconductor layer; a second undoped semiconductor layer on the first undoped semiconductor layer; a third undoped semiconductor layer between the first undoped semiconductor layer and the second undoped semiconductor layer, wherein the third undoped semiconductor layer includes a material different from that of the first undoped semiconductor layer; and a second doped semiconductor layer on the second undoped semiconductor layer, having a different conductivity from that of the first doped semiconductor layer; wherein the tunneling structure has a polarization field enhanced by the third undoped semiconductor layer.

### BACKGROUND

1. Technical Field

The present disclosure relates to a light-emitting element, and more particularly, to a light-emitting element having a tunneling structure.

2. Description of the Related Art

A lightemitting element, such as a light-emitting diode (LED), has been applied widely in optical display devices, traffic signals, data storing devices, communication devices, illumination devices, and medical apparatuses. The LED can be further packaged and connected with other elements to form a light-emitting device. FIG. 1 shows a schematic view of a conventional light-emitting device. A conventional light-emitting device 1 includes a submount 12 with a circuit 120; a solder 14 on the submount 12, wherein an LED 1 is fixed on the submount 12 by the solder 14; and an electrical-connecting structure 16 electrically connecting the electrodes 11, 13 with the circuit 120. The submount 12 can be a lead frame or a mounting substrate for circuit design and heat dissipation of the light-emitting device 10.

### SUMMARY OF THE DISCLOSURE

A light-emitting element includes a first light-emitting stacked structure including a first active layer; and a tunneling structure on the light-emitting stacked structure including a first doped semiconductor layer; a first undoped semiconductor layer on the first doped semiconductor layer; a second undoped semiconductor layer on the first undoped semiconductor layer; a third undoped semiconductor layer between the first undoped semiconductor layer and the second undoped semiconductor layer, wherein the third undoped semiconductor layer includes a material different from that of the first undoped semiconductor layer; and a second doped semiconductor layer on the second undoped semiconductor layer, having a different conductivity from that of the first doped semiconductor layer; wherein the tunneling structure has a polarization field enhanced by the third undoped semiconductor layer.

### BRIEF DESCRIPTION OF THE DRAWINGS

The accompanying drawings are included to provide easy understanding of the application, are incorporated herein and constitute a part of this specification. The drawings illustrate embodiments of the application and, together with the description, serve to illustrate the principles of the application.

FIG. 1 illustrates a cross-sectional view of a conventional light-emitting device.

FIG. 2A illustrates a cross-sectional view of a light-emitting element in accordance with an embodiment of the present application.

FIG. 2B illustrates a cross-sectional view of a tunneling structure shown in FIG. 2A.

FIG. 3 illustrates a cross-sectional view of a light-emitting element in accordance with another embodiment of the present application.

FIG. 4 illustrates an explosive diagram of a bulb in accordance with another embodiment of the present application.

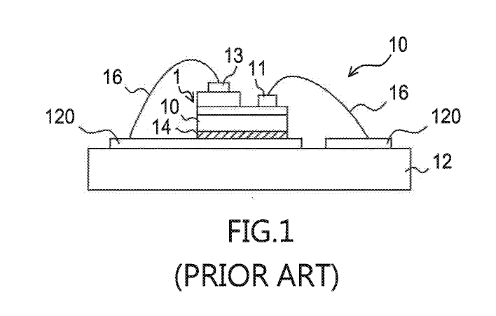

### DESCRIPTION OF THE PREFERRED EMBODIMENTS

To better and concisely explain the disclosure, the same name or the same reference number given or appeared in different paragraphs or figures along the specification should has the same or equivalent meanings while it is once defined anywhere of the disclosure.

The following shows the description of the embodiments of the present disclosure in accordance with the drawings.

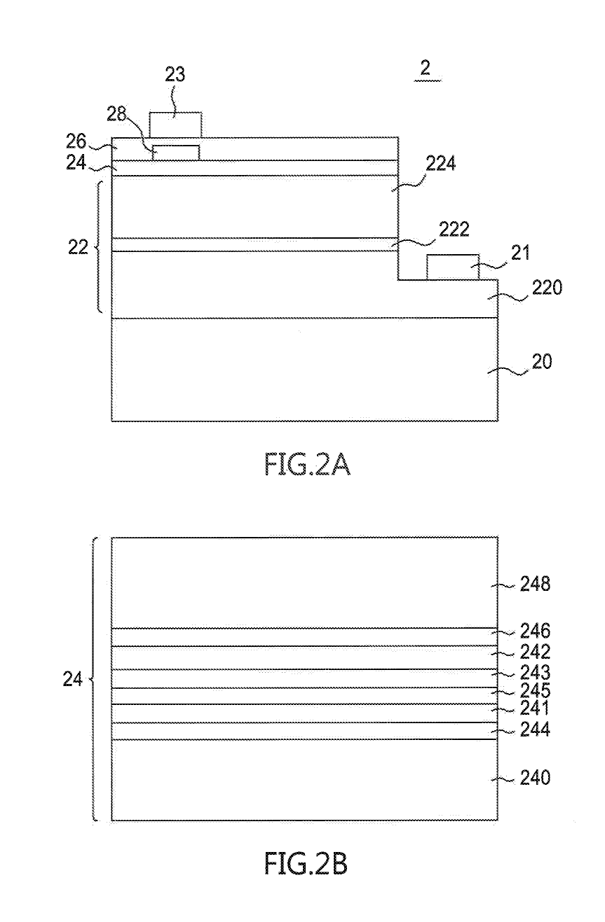

Referring o FIG. 2A, a light-emitting element 2 includes a substrate 20; a first light-emitting stacked structure 22 on the substrate 20; a tunneling structure 24 on the first light-emitting stacked structure 22; and a transparent conductive layer 26 on the tunneling structure 24. The first light-emitting stacked structure 22 includes a first light-emitting semiconductor layer 220; a first active layer 222 on the first light-emitting semiconductor layer 220; and a second light-emitting semiconductor layer 224 on the first active layer 222. There are a first electrode 21 and a second electrode 23 on the first light-emitting semiconductor layer 220 and the transparent conductive layer 26 respectively.

The substrate 20 can support the first light-emitting structure 22, the tunneling structure 24, and the transparent conductive layer 26. The material of the substrate 20 includes conductive material such as Diamond Like Carbon (DLC), graphite, carbon fiber, Metal Matrix Composite (MMC), Ceramic Matrix Composite (CMC), Polymer Matrix Composite (PMC), Ni, Cu, Al, Si, ZnSe, GaAs, SiC, GaP, GaAsP, ZnSe, InP, LiGaO₂, LiAlO₂, or the combination thereof, or insulative material such as sapphire, diamond, glass, quartz, acryl, ZnO, AlN, or the combination thereof.

The first light-emitting stacked structure 22 can be directly grown on the substrate 20, or attached to the substrate 20 by a bonding layer (not shown). The first light-emitting stacked structure 22 can be composed of semiconductor material(s) having one element selected from a group consisting of Ga, Al, In, As, P, N, Zn, Cd, and Se. The conductivities of the first light-emitting semiconductor layer 220 and the second light-emitting semiconductor layer 224 are different from each other. The first light-emitting semiconductor layer 220 and the second light-emitting semiconductor layer 224 can generate electrons and holes. The first active layer 222 can generate light with one or more colors. The light generated form the first light-emitting stacked structure 22 can be visible or non-visible. A structure of the first active layer 222 can include single heterostructure (SH), double heterostructure (DH), double-side double heterostructure (DDH), or multi-quantum well (MQW) structure.

The carriers can tunnel the tunneling structure 24 because of tunneling effect. Therefore, the series resistance of the light-emitting element 2 can be decreased. The tunneling structure 24 is configured that radiative recombination of the carriers cannot occur therein so it cannot generate light. Referring to FIG. 2B, the tunneling structure 24 includes a first doped semiconductor layer 240 on the first light-emitting stacked structure 22; a first undoped semiconductor layer 241 on the first doped semiconductor layer 240; a second undoped semiconductor layer 243 on the first undoped semiconductor layer 241; a third undoped semiconductor layer 245 between the first undoped semiconductor layer 241 and the second undoped semiconductor layer 243; and a second doped semiconductor layer 242 on the second undoped semiconductor layer 243, wherein the tunneling structure 24 has a polarization field enhanced by the third undoped semiconductor layer 245. The material of the third undoped semiconductor layer 245 can be different from that of the first undoped semiconductor layer 241 or the second undoped semiconductor layer 243 so the lattice mismatch exists between the third undoped semiconductor layer 245 and one of the first undoped semiconductor layer 241 or the second undoped semiconductor layer 243 and can enable charges at the interfaces among these undoped semiconductor layers, resulting in a large magnitude of the electric field. Therefore, the polarization field and the tunneling effect of the tunneling structure 24 both can be enhanced. The “undoped” could be understood that there is no chemical source introduced into the process chamber during forming the undoped semiconductor layer, but some minor dopants may be diffused from adjacent layers into the undoped layer after the undoped semiconductor layer is formed. The “doped” could be understood that there is chemical source introduced into the process chamber during forming the undoped semiconductor layer. Each of the first undoped semiconductor layer 241, the second undoped semiconductor layer 243, and the third undoped semiconductor layer 245 can have a thickness between 1 nm and 5 nm. The thickness of the first undoped semiconductor layer 241, the second undoped semiconductor layer 243, and the third undoped semiconductor layer 245 can be the same. The thicknesses of these undoped semiconductor layers can reduce optical absorption, tunneling barrier, and defect generation. A band gap of the third undoped semiconductor layer 245 can be larger than that of the first undoped semiconductor layer 241, that of the second undoped semiconductor layer 243, or both. This enables charges at the interfaces among these undoped semiconductor layers to create an electric field with a direction that enhances the tunneling current. Therefore, the tunneling effect of the tunneling structure 24 can be enhanced. Materials of the first undoped semiconductor layer 241 and the second undoped semiconductor layer 243 can be the same. The first undoped semiconductor layer 241 and the second undoped semiconductor layer 243 can, for example, include InGaN, and the third undoped semiconductor layer 245 can include AlGaN. A band gap of the first undoped semiconductor layer 241 can be smaller than that of the first doped semiconductor layer 240. This can generate an electric field to enhance the tunneling effect of the tunneling structure 24. A doping concentration of each of the first doped semiconductor layer 240 and the second doped semiconductor layer 242 is not less than 1E19 cm⁻³. The doping concentration of the first doped semiconductor layer 240 can be 1E19 cm⁻³ and the doping concentration of the second doped semiconductor layer 242 can be 3E19 cm⁻³, for instance. The doping concentration allow the alignment of the conduction and valence bands across the first undoped semiconductor layer 241, the second undoped semiconductor layer 243, and the third undoped semiconductor layer 245 for efficient interband tunneling and the tunneling effect of the tunneling structure 24 can be enhanced.

The tunneling structure 24 further includes a third doped semiconductor layer 244 between the first doped semiconductor layer 240 and the first undoped semiconductor layer 241; a fourth doped semiconductor layer 246 on the second doped semiconductor layer 242, and a fifth doped semiconductor layer 248 on the fourth doped semiconductor layer 246. The material of the third doped semiconductor layer 244 can be different from that of the first undoped semiconductor layer 241 or the first doped semiconductor layer 240 so the lattice mismatch exists between the third doped semiconductor layer 244 and one of the first undoped semiconductor layer 241 or the first doped semiconductor layer 240 and can enhance the polarization field within the tunneling structure 24. Therefore, the tunneling effect of the tunneling structure 24 can be enhanced. A doping concentration of the third doped semiconductor layer 244 is larger than that of the first doped semiconductor layer 240. The doping concentration of the third doped semiconductor layer 244 can, for instance, be 3E19 cm⁻³ and the doping concentration of the first doped semiconductor layer 240 can be 1E19 cm⁻³. This doping concentration introduces sufficient charges to decrease the depletion width for efficient tunneling. A thickness of the third doped semiconductor layer 244 is smaller than that of the first doped semiconductor layer 240. The thickness of the third doped semiconductor layer 244 can, for instance, be 5 nm and the thickness of the first doped semiconductor layer 240 can be 100 nm. The thicknesses of the third doped semiconductor layer 244 can reduce tunneling barrier. The third doped semiconductor layer 244 includes a band gap larger than that of the first doped semiconductor layer 240. The material of the third doped semiconductor layer 244 can be AlGaN and the material of the first doped semiconductor layer 240 can be GaN, for instance. Because of the larger mismatch at the interface between AlGaN and GaN, the magnitude of the electric field within the tunneling structure 24 is further enlarged.

Furthermore, the material of the fourth doped semiconductor layer 246 can be different from that of the second doped semiconductor layer 242 or the fifth doped semiconductor layer 248 so the lattice mismatch exists between the fourth doped semiconductor layer 246 and one of the first second doped semiconductor layer 242 or the fifth doped semiconductor layer 248 to lower the conduction band offset and to allow improved intraconduction band tunneling. Therefore, the tunneling effect of the tunneling structure 24 can be enhanced as well. A doping concentration of the fourth doped semiconductor layer 246 is about the same as that of the second doped semiconductor layer 242. The doping concentration of the fourth doped semiconductor layer 246 can, for instance, be 3E19 cm⁻³ and doping concentration of the second doped semiconductor layer 242 can be 3E19 cm⁻³. The effect of these doping concentrations is sufficient to introduce charges to decrease the depletion width for efficient tunneling. A thickness of the fourth doped semiconductor layer 246 is smaller than that of the second doped semiconductor layer 242. The thickness of the fourth doped semiconductor layer 246 can, for instance, be 1 nm and the thickness of the second doped semiconductor layer 242 can be 5 nm. By insertion of these doped semiconductor layers with these thicknesses, a region with an extra electric field is created in these doped semiconductor layers. This benefits the enhancement of the magnitude of the electric field under reverse bias conditions. The fourth doped semiconductor layer 246 includes a band gap smaller than that of the second doped semiconductor layer 242. The material of the fourth doped semiconductor layer 246 can be InGaN and the material of the second doped semiconductor layer 242 can be GaN, for instance. The InGaN layer lowers the conduction band offset, allowing intraconduction band tunneling. This enhances the current passing through the tunneling structure 24. A doping concentration of the fourth doped semiconductor layer 246 is larger than that of the fifth doped semiconductor layer 248. The doping concentration of the fourth doped semiconductor layer 246 can, for instance, be 3E19 cm⁻³ and doping concentration of the fifth doped semiconductor layer 248 can be 5E18 cm⁻³. The doping concentration of the fourth doped semiconductor layer 246 is sufficient to align conduction and valence bands through the tunneling structure 24 for enhancing the tunneling current. The doping concentration of the fifth doped semiconductor layer 248 can improve the ohmic contact between the tunneling structure 24 and the transparent conductive layer 26 as well. A thickness of the fourth doped semiconductor layer 246 is smaller than that of the fifth doped semiconductor layer 248. The thickness of the fourth doped semiconductor layer 246 can, for instance, be 1 nm and the thickness of the fifth doped semiconductor layer 248 can be 200 nm. The fourth semiconductor doped layer 246 can create an extra electric field in these doped semiconductor layer. The fourth doped semiconductor layer 246 includes a band gap smaller than that of the fifth doped semiconductor layer 248. The material of the fourth doped semiconductor layer 246 can be InGaN and the material of the fifth doped semiconductor layer 248 can be GaN, for instance. The band gap and the semiconductor material of the fifth doped semiconductor layer 248 can improve the ohmic contact between the tunneling structure 24 and the transparent conductive layer 26.

The transparent conductive layer 26 can electrically conduct and spread current to improve the light-emitting efficiency of the light-emitting element 2, and be transparent to the light emitted from the light-emitting structure 22. The transparent conductive layer 26 can further include a plurality of sub-layers(not shown). The material of the transparent conductive layer 26 can be transparent conductive material. including but not limited to ITO, InO, SnO, CTO, ATO, AZO, ZTO, ZnO, IZO, DLC, GZO, and so on.

The light-emitting element 2 can further include a current-blocking layer 28 between the tunneling structure 24 and the transparent conductive layer 26 for improving current spreading. The current-blocking layer 28 can be enclosed by the transparent conductive layer 26 and be located right under the second electrode 23. The material of the current-blocking layer 28 can be insulative material such as Su8, benzocyclobutene (BCB), perflorocyclobutane (PFCB), epoxy, acrylic resin, cyclic olefin copolymers (COC), polymethyl methacrylate (PMMA), polyethylene terephthalate (PET), polyimide (PI), polycarbonate (PC), polyetherimide, fluorocarbon polymer, glass, Al₂O₃, SiO₂, TiO₂, SiNₓ, spin-on-glass (SOG), or tetraethoxysilane (TEOS).

The first electrode 21 and the second electrode 23 are used to undergo an external voltage, and can be made of a transparent conductive material, a metallic material, or both. The transparent conductive material includes but is not limited to ITO, InO, SnO, CTO, ATO, AZO, ZTO, ZnO, IZO, DLC, GZO, IWO, GaP, or any combination thereof. The metal material includes but is not limited to Cu, Al, Sn, Au, Pt, Zn, Ag, Ti, Ni, Pb, Cr, Cd, Mg, Sb, Rh, or any combination thereof.

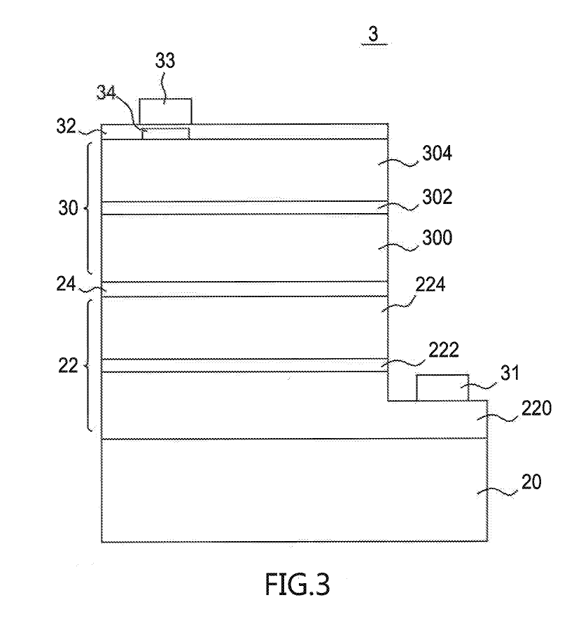

Referring to FIG. 3, a light-emitting element 3 includes the substrate 20; the first light-emitting stacked structure 22 on the substrate 20; the tunneling structure 24 on the first light-emitting stacked structure 22; a second light-emitting stacked structure 30 on the tunneling structure 24, and a transparent conductive layer 32 on the tunneling structure 24. The second light-emitting stacked structure 30 includes a third light-emitting semiconductor layer 300; a second active layer 302 on the third light-emitting semiconductor layer 300; and a fourth light-emitting semiconductor layer 304 on the second active layer 302. There are a first electrode 31 and a second electrode 33 on the first light-emitting semiconductor layer 220 and the transparent conductive layer 32 respectively. The carriers can tunnel the tunneling structure 24 because of tunneling effect. Therefore, the series resistance of the light-emitting element 3 can be decrease. In addition, the light-emitting element 3 can include a current-blocking layer 34 between the second light-emitting stacked structure 30 and the transparent conductive layer 32 for improving current spreading.

The second light-emitting stacked structure 30 can be directly grown on the tunneling structure 24, or attached to the tunneling structure 24 by a bonding layer (not shown). The second light-emitting stacked structure 30 can be composed of semiconductor material(s) having one element selected from a group consisting of Ga, Al, In, As, P, N, Zn, Cd, and Se. The conductivities of the third semiconductor layer 300 and the fourth semiconductor layer 304 are different from each other. The third semiconductor layer 300 and the fourth semiconductor layer 304 can generate electrons and holes. The second active layer 302 can generate light with one or more colors. The light generated form the second light-emitting stacked structure 30 can be visible or non-visible. A structure of the second active layer 302 can include single heterostructure (SH), double heterostructure (DH), double-side double heterostructure (DDH), or multi-quantum well (MQW) structure.

The tunneling structure 24 is configured that carriers can tunnel therein because of tunneling effect. Therefore, the series resistance of the light-emitting element 3 can be decreased. The tunneling structure 24 is configured that radiative recombination of the carriers cannot occur therein so it cannot generate light.

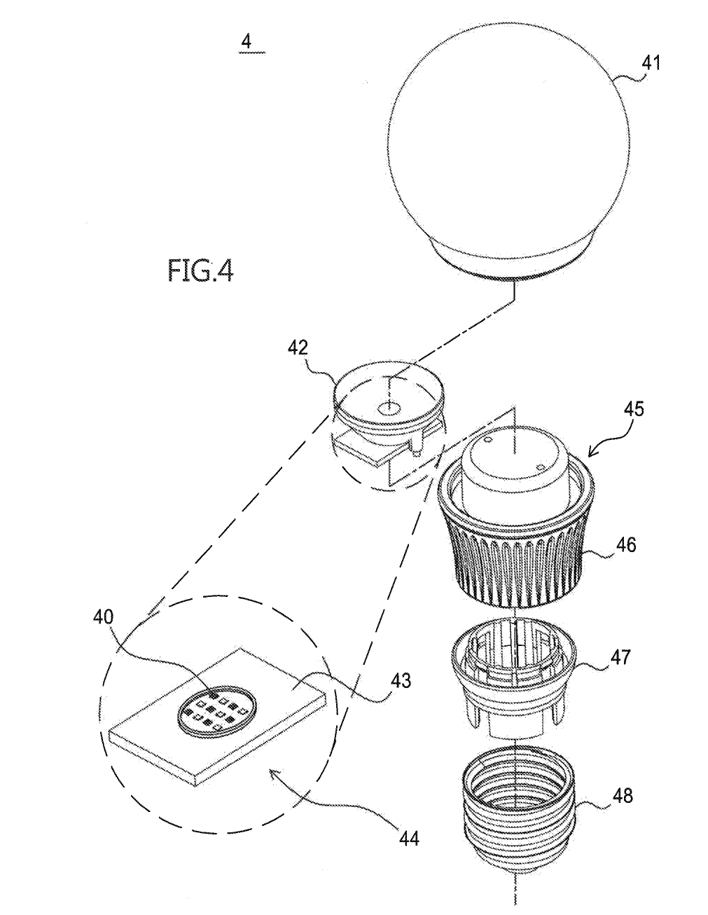

FIG. 4 shows an explosive diagram of a bulb in accordance with another application of the present application. The bulb 4 includes a cover 41, a lens 42, a lighting module 44, a lamp holder 45, a heat sink 46, a connecting part 47, and an electrical connector 48. The lighting module 44 includes a carrier 43 and a plurality of light-emitting elements 40 of any one of the above mentioned embodiments on the carrier 43.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting element, comprising:
a first light-emitting stacked structure comprising a first active layer; and
a tunneling structure on the light-emitting stacked structure, comprising:
a first doped semiconductor layer;
a first undoped semiconductor layer on the first doped semiconductor layer;
a second undoped semiconductor layer on the first undoped semiconductor layer;
a third undoped semiconductor layer between the first undoped semiconductor layer and the second undoped semiconductor layer, wherein the third undoped semiconductor layer comprises a material different from that of the first undoped semiconductor layer; and
a second doped semiconductor layer on the second undoped semiconductor layer, having a different conductivity from that of the first doped semiconductor layer;
wherein the tunneling structure has a polarization field enhanced by the third undoped semiconductor layer.

2. The light-emitting element of claim I, wherein the tunneling structure comprises a third doped semiconductor layer between the first undoped semiconductor layer and the first doped semiconductor layer, and the third doped semiconductor layer comprises a material different from that of the first doped semiconductor layer.

3. The light-emitting element of claim 2, wherein a doping concentration of the third doped semiconductor layer is larger than that of the first doped semiconductor layer.

4. The light-emitting element of claim 2, wherein a thickness of the third doped semiconductor layer is smaller than that of the first doped semiconductor layer.

5. The light-emitting element of claim 2, wherein the third doped semiconductor layer comprises a band gap larger than that of the first doped semiconductor layer.

6. The light-emitting element of claim 2, wherein the third doped semiconductor layer comprises AlGaN.

7. The light-emitting element of claim 1, wherein the tunneling structure comprises a fourth doped semiconductor layer on the second doped semiconductor layer, and the fourth doped semiconductor layer comprises a material different from that of the second doped semiconductor layer.

8. The light-emitting element of claim 7, wherein a doping concentration of the fourth doped semiconductor layer is about the same as that of the second doped semiconductor layer.

9. The light-emitting element of claim 7, wherein a thickness of the fourth doped semiconductor layer is smaller than that of the second doped semiconductor layer.

10. The light-emitting element of claim 7, wherein the fourth doped semiconductor layer comprises InGaN.

11. The light-emitting element of claim 7, wherein the fourth doped semiconductor layer comprises a band gap smaller than that of the second doped semiconductor layer.

12. The light-emitting element of claim 1, wherein thicknesses of the first undoped semiconductor layer, the second undoped semiconductor layer, and the third undoped semiconductor layer are about he same.

13. The light-emitting element of claim 1, wherein each of the first undoped semiconductor layer, the second undoped semiconductor layer, and the third undoped semiconductor layer has a thickness between 1 and 5 nm.

14. The light-emitting element of claim 1, further comprising a second light-emitting stacked structure on the tunneling structure, comprising a second active layer.

15. The light-emitting element of claim 1, further comprising a transparent conductive layer on the tunneling structure.

16. The light-emitting element of claim 1, wherein a band gap of the third undoped semiconductor layer is larger than that of the first undoped semiconductor layer, that of the second undoped semiconductor layer, or both.

17. The light-emitting element of claim 1, wherein materials of the first undoped semiconductor layer and the second undoped semiconductor layer are substantially the same.

18. The light-emitting element of claim 1, wherein the first undoped semiconductor layer comprises InGaN.

19. The light-emitting element of claim 1, wherein a band gap of the first undoped semiconductor layer is smaller than that of the first doped semiconductor layer.

20. The light-emitting element of claim 1, wherein each of the first doped semiconductor layer and the second doped semiconductor layer has a doping concentration greater than 1E19 cm⁻³.
